(19) United States
(12) Patent Application Publication
(10) Pub. No.: US 2026/0363035 A1
(43) Pub. Date: Nov. 12, 2026

(54) IN-SITU HIGH ASPECT RATIO ETCH WITH A RE-DEPOSITED HELMET MASK

(71) Applicant: Lam Research Corporation, Fremont, CA (US)

(72) Inventors: Walter Thomas RALSTON, San Jose, CA (US); Taner OZEL, Fremont, CA (US); Merrett WONG, Palo Alto, CA (US)

(21) Appl. No.: 19/515,672

(22) PCT Filed: Sep. 4, 2024
(86) PCT No.: PCT/US2024/045103

§ 371 Date: Mar. 2, 2026

Related U.S. Application Data
(60) Provisional application No. 63/581,521, filed on Sep. 8, 2023.

(51) Int. Cl. H10P 76/40; C23C 16/06; C23C 16/455; C23C 16/505; H01J 37/32; H10P 14/60; H10P 50/00

(52) U.S. Cl. CPC H10P 76/4085; C23C 16/06; C23C 16/45538; C23C 16/505; H01J 37/32449; H10P 14/6336; H10P 14/6339; H10P 50/73; H01J 2237/04735; H01J 2237/3321; H01J 2237/334

(57) ABSTRACT

A method for etching features in a stack below a patterned mask is provided. The stack is partially etched through the patterned mask. A helmet mask is deposited over the patterned mask by providing at least one cycle of pretreating surfaces of the patterned mask and after pretreating surfaces of the patterned mask, selectively depositing a metal containing helmet layer on surfaces of the patterned mask. The stack is etched through the helmet mask.

### CROSS-REFERENCE TO RELATED APPLICATION

This application claims the benefit of priority of U.S. Application No. 63/581,521, filed Sep. 8, 2023, which is incorporated herein by reference for all purposes.

### BACKGROUND

The disclosure relates to a method of forming semiconductor devices on a semiconductor wafer.

In forming semiconductor devices, etch layers may be etched to form memory holes or lines, or other semiconductor features. Some semiconductor devices may be formed by etching a single stack of silicon dioxide also known as silicon oxide (SiO2), for example, to form a capacitor in dynamic access random memory (DRAM). Other semiconductor devices may be formed by etching stacks of bilayers of alternating silicon dioxide (oxide) and silicon nitride (nitride) (ONON), or alternating silicon dioxide and polysilicon (OPOP). Other stacks of alternating layers may be etched. Some of the stacks of alternating layers may have one of the layers of the alternating layers that is silicon oxide. Some alternating layers may be alternating trilayers. Such stacks may be used in memory applications and three dimensional “not and” gates (3D NAND). These stacks tend to require a relatively high aspect ratio (HAR) etching of the dielectrics. For high aspect ratio etches, examples of desired etch characteristics are high etch selectivity to the mask (such as an amorphous carbon mask), low sidewall etching with straight profiles, and high etch rate at the etch front. Some high aspect ratio etches result in tapered features that are much wider at the top than the bottom. Such features may increase device failure or limit device density, device performance, and device depth.

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

### SUMMARY

To achieve the foregoing and in accordance with the purpose of the present disclosure, a method for etching features in a stack below a patterned mask is provided. The stack is partially etched through the patterned mask. A helmet mask is deposited over the patterned mask by providing at least one cycle of pretreating surfaces of the patterned mask and after pretreating surfaces of the patterned mask, selectively depositing a metal containing helmet layer on surfaces of the patterned mask. The stack is etched through the helmet mask.

In another manifestation, an apparatus for etching features in a stack is provided. A process chamber is provided. A substrate support supports a substrate inside the process chamber. A power source provides power in the process chamber. A gas source is in fluid connection with the process chamber where the gas source comprises an etch gas source, a pretreatment gas source, and a deposition gas source. A controller is controllably connected to the power source and the gas source and is configured to etch features in a stack below a patterned mask, by a process comprising a) partially etching the stack through the patterned mask using an etch gas from the etch gas source, depositing a helmet mask over the patterned mask, comprises at least one cycle of pretreating surfaces of the patterned mask using a pretreatment gas from the pretreatment gas source and after pretreating surfaces of the patterned mask, selectively depositing a metal containing helmet layer on surfaces of the patterned mask using a deposition gas from the deposition gas source, and etching stack through the helmet mask using the etch gas from the etch gas source.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of processes used in some embodiments.

FIGS. 2A-E are schematic cross-sectional views of a stack processed according to some embodiments.

FIG. 3 is a schematic view of an etch chamber that may be used in some embodiments.

FIG. 4 is a schematic view of a computer system that may be used in practicing some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Dry development of high aspect ratio contacts requires strict control of the tapering angle of the sidewall. Various methods try to limit lateral critical dimension (CD) differences between the top and bottom parts of the etched structures. With the recent development of DRAM memory having smaller-sized higher aspect ratio features or 3D NAND memory having thicker structures with an increased number of ONON or OPOP bilayers, the demand for tight control of top and bottom geometries is especially significant. In case the profile (difference between the top and bottom CDs) increases, subsequent steps of device manufacturing will be at risk that will impact device performance. In the current technology, reactive ion etching of high aspect ratio structures relies on sidewall deposition to protect against CD lateral erosion. A delicate balance between etching and sidewall deposition is especially difficult to maintain for high aspect ratio features. As a result, high aspect ratio dry development is limited to thinner structures and requires significant complex development to enable a thick stack to be etched.

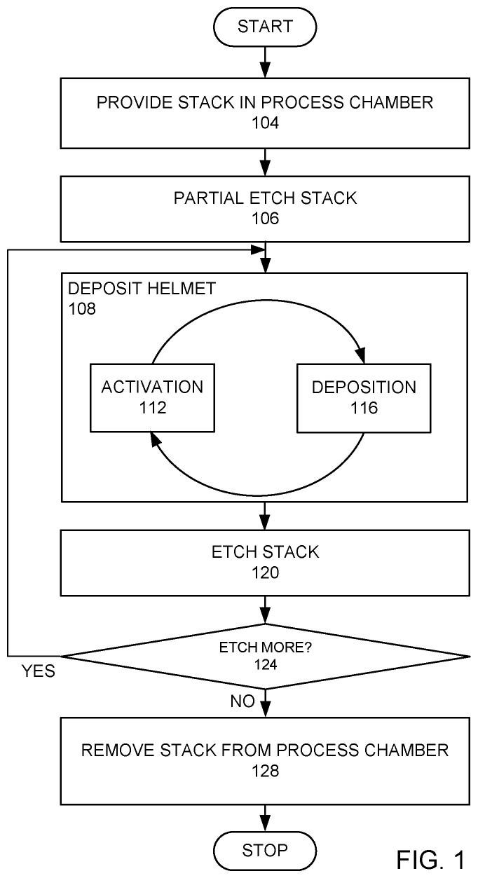

Embodiments described herein provide an in-situ process for providing deeper high aspect ratio features etched in a stack, where widths of the features near the top of the features are about equal to widths of the features near the bottoms of the features. To facilitate understanding, FIG. 1 is a high level flow chart that may be used in some embodiments. A stack is provided into a process or etch chamber (step 104). In some embodiments, the stack is placed on a substrate support in the process chamber.

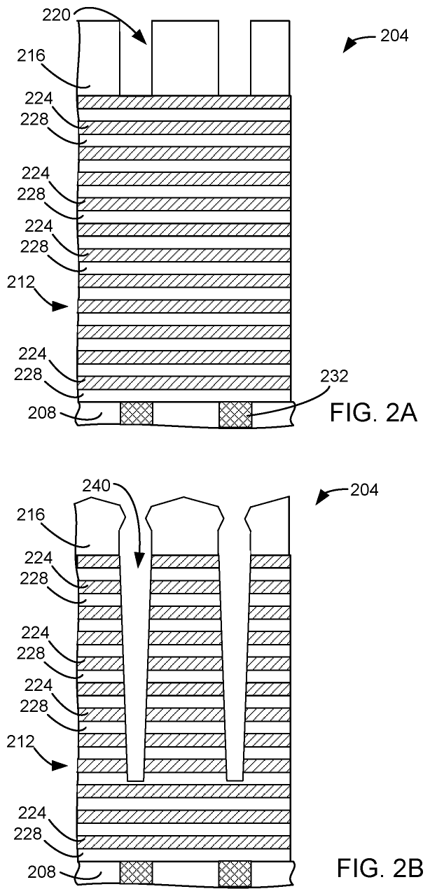

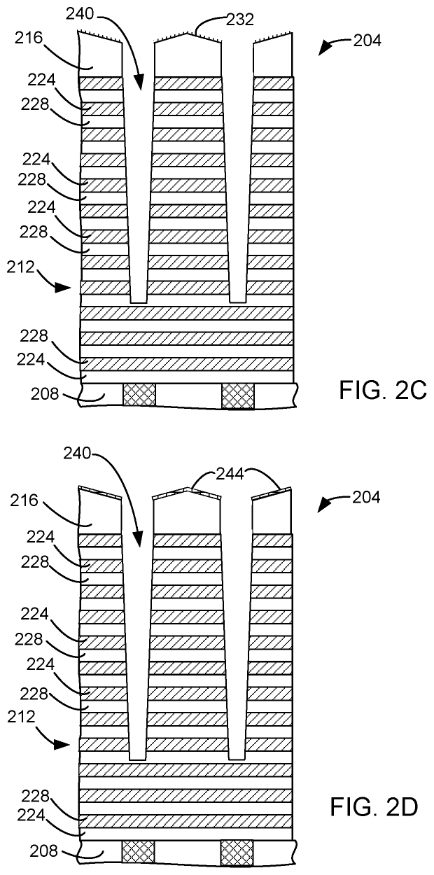

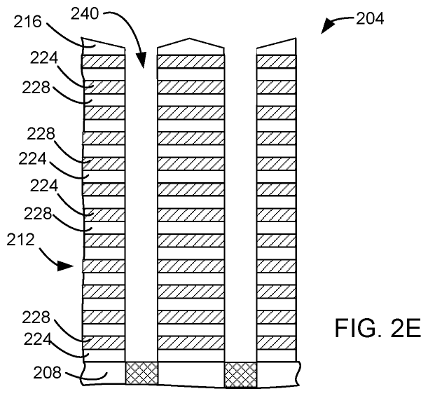

FIG. 2A is a schematic cross-sectional view of a stack 204 that may be etched in some embodiments. In some embodiments, the stack 204 comprises a substrate 208 under a plurality of bilayers 212 disposed below a patterned mask 216. In some embodiments, one or more layers may be disposed between the substrate 208 and the plurality of bilayers 212 and/or the plurality of bilayers 212 and the patterned mask 216. In some embodiments, the patterned mask 216 is a metal or metalloid containing mask. In some embodiments, a plasma enhanced physical vapor deposition (PECVD) is used to deposit a metal containing dielectric film that may be used as a mask. A method of using PECVD to deposit a tungsten carbide film is described in U.S. Pat. No. 9,875,890, entitled “Deposition of Metal Dielectric Film for Hardmask,” issued on Jan. 23, 2018, which is incorporated by reference for all purposes and may be used in some embodiments. In some embodiments, the deposited tungsten carbide film is patterned to form the patterned mask 216. In some embodiments, the patterned mask 216 is a carbon containing amorphous carbon mask. In some embodiments, the mask is metal and metalloid free. In some embodiments, the patterned mask pattern provides mask features 220 for high aspect ratio contacts. In some embodiments, the mask features 220 are formed before the stack 204 is placed in the etch chamber. In other embodiments, the mask features 220 are formed while the stack 204 is in the etch chamber. In some embodiments, each bilayer 212 includes a layer of silicon oxide 224 and a layer of silicon nitride 228.

The stack is partially etched (step 106). In some embodiments, an etching gas is provided. In some embodiments, radio frequency (RF) power is provided to transform the etching gas into a plasma with etching ions. A voltage is applied to accelerate etching ions from the plasma to the stack. The etching ions partially etch the stack and etch some of the mask. The etching of the stack may comprise at least one of a chemical etching and physical sputtering of the stack.

FIG. 2B is a schematic cross-sectional view of a stack 204 after the stack 204 has been partially etched forming etch features 240. Part of the mask 216 has been etched away. During the partial etch, the patterned mask 216 is partially etched and reshaped. In the example shown in FIG. 2B, the patterned mask 216 has sidewall deposition, so that the patterned mask 216 becomes necked forming a narrow portion. The neck causes the features 240 to be tapered. If the etch was continued the features 240 would become even more tapered.

A helmet mask is deposited over the patterned mask 216 (step 108). In some embodiments, the deposition of the helmet mask comprises one or more cycles of a step of pretreating surfaces of the patterned mask (step 112) and a step of depositing a metal containing helmet layer on the surfaces of the patterned mask (step 116). During the step of pretreating surfaces of the patterned mask (step 112) a pretreatment gas is provided. In some embodiments, the pretreatment gas comprises a hydrogen containing component gas. In some embodiments, the pretreatment gas comprises hydrogen gas. The hydrogen gas provides a reduction chemistry. In some embodiments, with a pretreatment gas with a hydrogen containing component, the pretreatment gas is oxygen free. In some embodiments, the pretreatment gas comprises a silicon containing gas. In some embodiments, the pretreatment gas comprises at least one of silicon tetrachloride (SiCl₄), silicon tetrafluoride (SiF₄), and silane (SiH₄). The pretreatment gas is transformed into a plasma. In some embodiments, RF power or non-RF power is used to transform the pretreatment gas into plasma. In some embodiments, RF power is provided at one or more frequencies at 400 kilohertz (kHz), 60 megahertz (MHz), 2 MHz, and 27 MHz. In some embodiments, the plasma is generated in the process chamber where the stack is located. In some embodiments, the plasma is generated remotely and then supplied to the process chamber. In some embodiments, the remote plasma is generated in a part of the process chamber that is separated from where the stack is located and then flowed to the part of the process chamber where the stack is located.

FIG. 2C is a schematic cross-sectional view of a stack 204 after the mask 216 has been subjected to a step of pretreating surfaces of the patterned mask (step 112), creating pretreated surfaces 232 of the patterned mask 216. In some embodiments, the pretreating surfaces of the patterned mask (step 112) removes some of the necking. In some embodiments, the mask shaping reduces the height of the patterned mask 216. In some embodiments, the pretreating surfaces of the patterned mask (step 112) provides a reduction chemistry to provide the surface with a chemical reduction chemistry. In some embodiments, the pretreatment creates dangling bonds on the pretreated surfaces 232.

During the step of depositing a metal containing helmet layer on the surfaces of the patterned mask (step 116) a deposition gas comprising at least one of a metal fluoride gas, silane (SiH₄) gas, or germane (GeH₄) gas is provided. In some embodiments, deposition gas comprises one or more of tungsten hexafluoride (WF₆), a rhenium fluoride, such as hexafluoride (ReF₆) or rhenium heptafluoride (ReF₇), a molybdenum fluoride, such as molybdenum hexafluoride (MoF₆), a tantalum fluoride, such as tantalum pentafluoride (TaF₅), and a vanadium fluoride, such as vanadium pentafluoride (VF₅). The deposition gas is transformed into a plasma. In some embodiments, RF power or non-RF power is used to transform the pretreatment gas into plasma. In some embodiments, RF power is provided at one or more frequencies at 400 kilohertz (kHz), 60 megahertz (MHz), 2 MHz, and 27 MHz. In some embodiments, the plasma is generated in the process chamber where the stack is located. In some embodiments, the plasma is generated remotely and then supplied to the process chamber. In some embodiments, the remote plasma is generated in a part of the process chamber that is separated from where the stack is located and then flowed to the part of the process chamber where the stack is located.

FIG. 2D is a schematic cross-sectional view of a stack 204 after a step of depositing a metal containing helmet layer on the surfaces of the patterned mask (step 116) where a helmet layer 244 is deposited. The drawing is not to scale in order to better illustrate the helmet layer 244. In some embodiments, a single helmet layer 244 is a single atomic or molecular layer. In some embodiments, a single helmet layer 244 is more than a single atomic or molecular layer.

In some embodiments, the helmet mask deposition (step 108) comprises one or more cycles of a step of pretreating surfaces of the patterned mask (step 112) and a step of depositing a metal containing helmet layer on the surfaces of the patterned mask (step 116). In some embodiments, the helmet mask deposition (step 108) is provided for two to ten cycles. In some embodiments, the completed helmet mask layer 244 after two to ten cycles has a thickness in the range of 5 nm to 100 nm. Since the deposition is a cyclical process that is completely or partly an atomic layer deposition process. In some embodiments, the partial atomic layer deposition process is also partly a plasma enhanced chemical vapor deposition process.

The stack is then further etched using the patterned mask 216 and the helmet mask layer 244 as a mask (step 120). In some embodiments, the helmet mask layer 244, shown in FIG. 2D and some of the patterned mask 216 are etched away. In some embodiments, the etching of the stack is continued until the etching of the stack is completed, as shown in FIG. 2E. In some embodiments, the depositing the helmet (step 108) and the further etching the stack (step 120) are cyclically repeated 2-10 times.

After the etch is complete other processes may be performed in the process chamber to further process the stack, such as removing any remaining patterned mask 216. After the processes are completed in the process chamber, the stack is removed from the process chamber. Since the etching (steps 106 and 120) and depositing the helmet (step 108) are performed in the same process chamber, the etching (steps 106 and 120) and depositing the helmet (step 108) are performed in-situ. The ability to perform the etching (steps 106 and 120) and depositing the helmet (step 108) in-situ removes the necessity of moving the stack between process chambers during such steps, increasing through-put, reducing cost, and reducing contamination that would be caused by moving the stack between process chambers. In addition, in some embodiments, performing the steps in-situ allows for each helmet mask layer to be thinner over more cycles since the substrate does not need to be removed from the chamber. In addition, an in-situ process allows for less disruptions in the mask shape and morphology during the process.

Some embodiments may be used on an Oxide/Nitride (ONON) multilayer stack to form features, such as contact holes or trenches, in making a 3D NAND memory device. Some embodiments may be used for dynamic random access memory (DRAM) Capacitor etching. Some embodiments may be used to etch silicon oxide and polysilicon bilayers (OPOP). Some embodiments provide an etch depth of greater than 1 micron. In some embodiments, the etch depth is greater than 10 microns. In some embodiments, the etch depth is in the range of 0.7 microns to 1.3 microns.

An advantage of some embodiments is the ability of a device manufacturer to be able to have a more precise control of the profile of a high aspect feature. Various embodiments enable increasing the bottom CD for very high aspect features. Various embodiments enable the next generations of devices that rely on deeper structures with higher aspect ratios. Various embodiments reduce the cost of device manufacturing by reducing the number of steps for the development of high aspect ratio contacts. Various embodiments reduce the variation of the width of the features along the depth of the features so that the difference between widths at any two points along the depth of the features 240 is less than 10%. In some embodiments, the deposition of the helmet mask allows for providing the sidewall liner. In some embodiments, the deposition of the helmet mask layer 244 provides an additional mask thickness so that the pattern mask is not completely removed. In some embodiments, the helmet mask layer 244 increases the mask allowing for a deeper etch. In addition, in some embodiments, the deposition of the helmet mask may also deposit a sidewall liner.

In some embodiments, the stack may be a single silicon containing layer, such as a single layer of silicon oxide, silicon nitride, or silicon. In some embodiments, the stack may comprise a single layer or multiple layers of other silicon containing materials. In some embodiments, for etching a stack with a silicon layer, the mask may further comprise oxygen. In some embodiments, for etching a silicon oxide stack, the mask may further comprise silicon. Some embodiments may have metal or metalloid dopants. In some embodiments, the metal in the metal or metalloid dopant is at least one of tungsten, molybdenum, ruthenium, tantalum, titanium, platinum, and aluminum. In other embodiments, the metalloid is boron.

In some embodiments, the features 240 may be etched the entire depth of the stack (i.e., close to touchdown) before the helmet mask layer 244 is deposited. In such embodiments, the helmet mask layer 244 is used as a mask for a process that widens the bottoms of the features 240 and reduces taper. A more aggressive etch than the partial etch may be used to widen the bottoms of the features 240. The helmet mask layer 244 provides additional mask protection while widening the bottom of the features 240.

In some embodiments, sidewall liner deposition may be performed before, during, or after the deposition of the helmet mask layer. The sidewall liner deposition may be carbon based or may be of another material, such as a metal or metalloid containing material. In some embodiments, the deposition of sidewall liners is part of the helmet mask layer 244 formation process. In some embodiments, no sidewall liner is deposited. In some embodiments, the timing and process of the deposition of the mask and sidewall liner may be used to tailor the mask deposition to the desired resulting features, such as reduced bow CD, improved bottom CD, reduced taper, reduced twisting, and reduced defect formation.

Some embodiments do not cause additional distortion of the mask shape and morphology. Various embodiments may be highly varied. Embodiments have been demonstrated to work on extremely small CD features, such as CDs in the range of 16 nm to 20 nm circular holes. It is expected that embodiments can apply to nodes/processes using smaller or larger CDs on a variety of substrate materials.

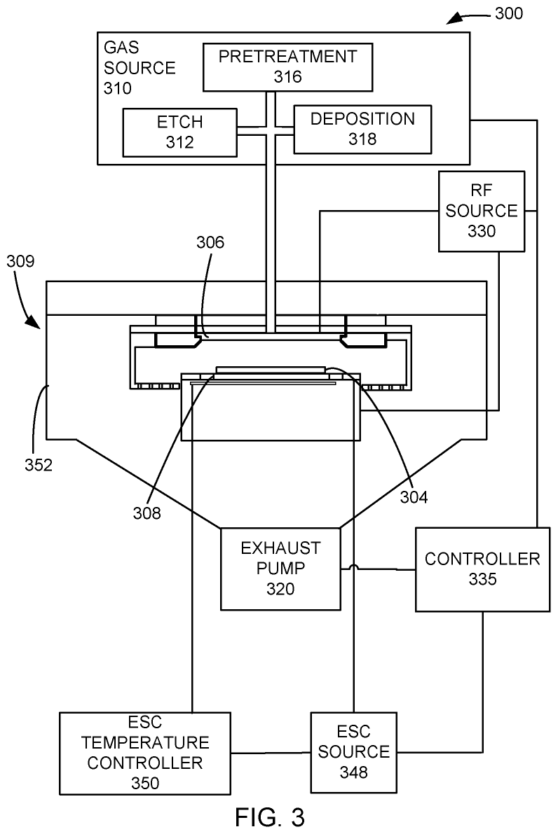

FIG. 3 is a schematic view of an etch reactor system 300 that may be used in some embodiments. In some embodiments, an etch reactor system 300 comprises a gas distribution plate 306 providing a gas inlet and an electrostatic chuck (ESC) 308, within an etch (or process) chamber 309, enclosed by a chamber wall 352. Within the etch chamber 309, a stack 304 is positioned over the ESC 308 that is used as a substrate support. The ESC 308 may provide a bias from the ESC source 348. An etch gas source 310 is connected to the etch chamber 309 through the gas distribution plate 306. An ESC temperature controller 350 is connected to the ESC 308. A radio frequency (RF) source 330 provides RF power to a lower electrode and/or an upper electrode, which in this embodiment are the ESC 308 and the gas distribution plate 306, respectively. In some embodiments, 400 kilohertz (kHz), 60 megahertz (MHz), and optionally, 2 MHZ, and 27 MHz power sources make up the RF source 330 and the ESC source 348. In some embodiments, the upper electrode is grounded. In some embodiments, one generator is provided for each frequency. In some embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 335 is controllably connected to the RF source 330, the ESC source 348, an exhaust pump 320, and the etch gas source 310. An example of such an etch chamber is the Vantex® etch system manufactured by Lam Research Corporation of Fremont, CA. The process chamber can be a CCP (capacitively coupled plasma) reactor or an ICP (inductively coupled plasma) reactor.

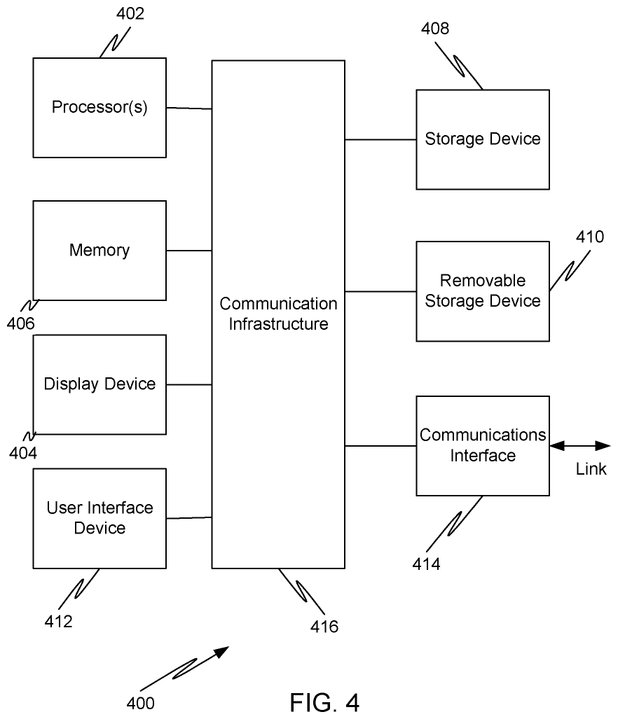

FIG. 4 is a high level block diagram showing a computer system 400, which is suitable for implementing the controller 335 used in embodiments. The computer system 400 may have many physical forms ranging from an integrated circuit, a printed circuit board, and a small handheld device up to a huge supercomputer. The computer system 400 includes one or more processors 402 and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communications interface 414 (e.g., wireless network interface). The communications interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communications link that carries signals and may be implemented using wire or cable, fiber optics, a phone line, a cellular phone link, a radio frequency link, and/or other communications channels. With such a communications interface 414, it is contemplated that the one or more processors 402 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that is executed by a computer using an interpreter. Computer readable media may also be computer code transmitted by a computer data signal embodied in a carrier wave and representing a sequence of instructions that are executable by a processor.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for etching features in a stack below a patterned mask, comprising:
a) partially etching the stack through the patterned mask;
b) depositing a helmet mask over the patterned mask, comprises at least one cycle of:
pretreating surfaces of the patterned mask; and
after pretreating surfaces of the patterned mask, selectively depositing a metal containing helmet layer on surfaces of the patterned mask; and
c) etching the stack through the helmet mask.

2. The method, as recited in claim 1, wherein the pretreated surfaces of the patterned mask, comprises:
providing a pretreatment gas comprising at least one of a hydrogen gas and a silicon containing gas; and
transforming the pretreatment gas into a plasma.

3. The method, as recited in claim 2, wherein the silicon containing gas comprises at least one of SiCl₄, SiF₄, SiH₄.

4. The method, as recited in claim 1, wherein the pretreating surfaces of the patterned mask shapes the patterned mask.

5. The method, as recited in claim 1, wherein the pretreating surfaces of the patterned mask and the selectively depositing the metal containing helmet layer are non-overlapping.

6. The method as recited in claim 1, wherein the selectively depositing the metal containing helmet layer, comprises:
providing a deposition gas comprising a metal fluoride gas; and
transforming the deposition gas into a plasma.

7. The method, as recited in claim 6, wherein the metal fluoride gas comprises at least one of tungsten hexafluoride, a rhenium fluoride, a molybdenum fluoride, a tantalum fluoride, and a vanadium fluoride.

8. The method, as recited in claim 1, wherein the depositing of the helmet mask is performed for 2 to 10 cycles.

9. The method, as recited in claim 1, wherein the depositing of the helmet mask is an atomic layer deposition process.

10. The method, as recited in claim 1, wherein the helmet mask is deposited with a selectivity wherein a ratio of a thickness of deposition of the helmet mask on top of the mask to a thickness of deposition of the helmet mask at bottoms of features is in a range of 50:1 to 100:1.

11. The method, as recited in claim 1, wherein the helmet mask is deposited on top of the mask with a thickness in a range of 5 nm to 100 nm.

12. The method, as recited in claim 1, wherein the depositing the helmet mask is at least partly an atomic layer deposition process.

13. The method, as recited in claim 1, wherein the pretreated surfaces of the patterned mask, comprises:
providing a pretreatment gas comprising a hydrogen containing component; and
transforming the pretreatment gas into a plasma.

14. The method, as recited in claim 13, wherein the pretreatment gas is oxygen free.

15. The method, as recited in claim 1, wherein steps a, b, and c are performed in-situ.

16. The method, as recited in claim 1, wherein steps b and c are repeated at least once.

17. An apparatus for etching features in a stack, comprising:
a process chamber;
a substrate support for supporting a substrate inside the process chamber;
a power source for providing power in the process chamber;
a gas source in fluid connection with the process chamber, comprising:
an etch gas source;
a pretreatment gas source; and
a deposition gas source; and
a controller, controllably connected to the power source and the gas source, configured to etch features in a stack below a patterned mask, by a process comprising:
a) partially etching the stack through the patterned mask using an etch gas from the etch gas source;
b) depositing a helmet mask over the patterned mask, comprises at least one cycle of:
pretreating surfaces of the patterned mask using a pretreatment gas from the pretreatment gas source; and
after pretreating surfaces of the patterned mask, selectively depositing a metal containing helmet layer on surfaces of the patterned mask using a deposition gas from the deposition gas source; and
c) etching stack through the helmet mask using the etch gas from the etch gas source.

18. The apparatus, as recited in claim 17, wherein the deposition gas source provides a metal fluoride gas.

19. The apparatus, as recited in claim 17, wherein the pretreatment gas source provides at least one of a hydrogen containing component gas and a silicon containing g
